(19) United States
(12) Patent Application Publication
(10) Pub. No.: US 2012/0262618 A1
(43) Pub. Date: Oct. 18, 2012

(54) WATERPROOF CASE FOR HAND HELD COMPUTING DEVICE

(75) Inventor: Matthew Weakly, Fort Mill, SC (US)

(73) Assignee: AMPHIBIAN LABS LLC, Fort Mill, SC (US)

(21) Appl. No.: 13/447,237

(22) Filed: Apr. 15, 2012

Related U.S. Application Data
(60) Provisional application No. 61/517,146, filed on Apr. 14, 2011.

(51) Int. Cl. H04N 5/222; H05K 7/16; G06T 13/00; G06F 1/16; G06T 1/00; G06F 3/041

(52) U.S. Cl. 348/333.01; 345/522; 345/173; 345/473; 361/679.09; 361/679.15; 348/E05.022

(57) ABSTRACT

The invention comprises a waterproof housing, which protects and allows operation of a hand held computer 40 (FIG. 2) while underwater, an electronic dock 38 (FIG. 2) which interfaces with said computer, a pressure resistant user interface, and a software application installed on said computer which allows interaction with and access to native sensors and electronics for the purpose of providing a multifunctional diving apparatus. The invention provides function of an underwater camera and dive computer and associates collected sensor data with a dive event to automatically generate a dive log. Additionally the invention provides a novel touchscreen interface 85 (FIG. 10) suitable for underwater use.

### BACKGROUND

1. Field

The present invention relates generally to a waterproof case for a hand held computer or cell phone, and more particularly to a waterproof case containing an electronic device to provide multiple functions such as an underwater camera, diving computer, and to generate and store a dive log. Additionally the present invention relates to a user input apparatus that can be used while underwater and at elevated pressures.

2. Prior Art

Scuba divers have numerous electronic accessories available in the marketplace to enhance the safety, convenience, and overall diving experience. These devices are currently disparate with none providing multiple functions. The current solution for underwater photography is to either place a conventional camera in a waterproof housing or purchase a dedicated underwater camera. The current solution for providing dive computer functionality is to purchase a dedicated dive computer. The current solution for acquiring global positioning is to purchase a dedicated Global Positioning System receiver. There are numerous additional examples of dedicated devices performing only one required function for scuba divers necessitating the purchase of many expensive items.

Portable computers and cell phones have become common and are increasingly used to provide a diverse set of functionality on land. These devices are commonly equipped with cameras, Global Positioning System receivers, color displays, wireless transmitters and receivers of voice and data, digital compass, and other features enabling a wide variety of applications and uses. There is currently no commercial product offering the complete feature set of these devices for scuba diving or underwater sports.

Another deficiency of currently available electronic equipment for use by scuba divers is the lack of touchscreen input devices. The most common user interface for cellular phones and hand-held computing devices currently produced are touchscreen interfaces. The conventional touchscreen interface design will not operate at elevated water pressures. For the most common resistive layer type touchscreen elevated pressure will compress the outer surface and cause inadvertent contact between conductive layers. Some limited operation near the surface can be achieved by increasing the operational force or stiffness of the layers, but is detrimental to user comfort. The next most common touchscreen measures capacitance changes of a finger touching the surface of the touchscreen. Likewise this type of touchscreen is not suited for underwater use since the water in contact with the screen reduces or eliminates detectable changes in capacitance during a touch event. There is currently no commercially available touchscreen interface compatible with use for scuba diving.

Typical user input devices which operate under elevated water pressures are constructed with one or more push button switches. In order to operate under elevated water pressure the conventional push buttons utilize a spring to separate and maintain an air gap between the switch contacts. The spring force is selected to provide a counterforce to the elevated water pressure over the operational depth range of the device. These conventional input devices are limited to operation over a range of depths since the user must be able to comfortably overcome the force required to make switch contact near the surface where there is no assistance provided by water pressure.

Common electronic keypads are created by molding a deformable flexible layer positioned over a contact layer separated by an air gap. In the same way resistive touchscreens are not suited for use while diving; these keypads are likewise susceptible to compression of the air gap layer and inadvertent button press. Commercially available electronic keypads for use while diving must be specially designed to incorporate the aforementioned spring mechanism and compensating force and are subject the same deficiencies.

The most relevant prior art is patent application publication US 2011/0096633 Portable Diver Apparatus, Comprising A Portable Computing Device and an Add on Diver Device. Within this application a device is disclosed comprising a waterproof receptacle for a portable computing device, a keypad, and an electronic interface to the portable computing device. This device is limited to an electronic keypad embodiment for user interface. Within this application there is no disclosure as to how the keypad is able to operate at elevated pressures.

An additional deficiency of this prior art is that the electronic interface to the portable computing device is through a cable. This connection method is reused from the prior art referenced within the same patent application publication US 2011/0096633. This interface is problematic in that when the device is inserted the cable may pinch between the sections of the housing when closed and produce a leak during operation.

An additional deficiency of this prior art is the lack of disclosure for a software application on the portable computing device which interprets and responds to communications from the device and which must perform calculation and formulate graphical user interfaces for divers to view. There is currently no support for standard interfaces on these devices to perform this role without an installed software application and process for manipulating data.

The next most relevant prior art is a described by U.S. Pat. No. 6,819,866 Watertight Universal Housing. This apparatus was developed for use with multiple video cameras within a single “universal” housing. There is no disclosure for this device being used to control hand held computers or cell phones. Likewise there is no disclosure for this device comprising sensors to measure water pressure or other parameters relevant to diving. There is no disclosure to perform any additional functions outside of the original intended purpose of the installed device for example an installed video camera only functions as a video camera within the device.

In multiple aspects and characteristics of currently available electronic devices the present invention greatly improves the function of and enables additional capability to these electronic devices for scuba diving or other underwater sport. The present invention combines the functions of many disparate devices in a single device and provides a novel user interface for operation underwater and at elevated pressures.

### SUMMARY OF INVENTION

The present invention is a housing for protecting a hand held computer such as the Apple iPhone, providing user interface to the computer, providing sensor input to the computer, and providing transparent viewing of the computer's display while underwater. In another embodiment the present invention comprises a software application installed on the computer to perform calculation relevant to diving, provide an interface to said computer hardware and data storage elements, and provide a viewable graphical user interface.

The first aspect of the present invention provides a case for protecting a hand held computer under water, the case comprising:
(a) a waterproof housing defining a receptacle for holding the hand held computer;
(b) an electronic dock connected to the housing;
(c) a plurality of buttons extending from an outer surface of the housing and electronically connected to the electronic dock, wherein the buttons transmit control signals to the hand held computer through the electronic dock;
(d) one or a plurality of sensors electronically connected to the electronic dock, wherein data from the sensor or sensors is transmitted to the computer through the electronic dock.

The second aspect of the present invention is a combination of apparatus comprising:
(a) elements described in the first aspect;
(b) a computer;
(c) a software application installed on the computer.

The present invention when used with the hand held computer during diving provides multiple functions to the diver which may include diver computer, depth and temperature gauge, still and video camera, compass and other functions supported by the hand held computer. The present invention when used with a computer may comprise a software application installed on the computer. The software application receives sensor inputs, controls portable computer hardware, performs calculations and displays information to the diver on the portable computer's screen. The present invention reduces the need for disparate devices and combines functionality in a single product.

Another aspect of the present invention provides a novel touchscreen user input device suitable for operation underwater and at diving depths. The novel touchscreen separates the electrical contact layers with an incompressible dielectric fluid replacing the air gap common to resistive touchscreen devices. The novel touchscreen comprises flexible layer material to allow the dielectric liquid to flow away from between the layers directly under the user's finger during a touch event. This touchscreen allows operation and consistent touch activation force at the surface or while diving at elevated pressures.

### BRIEF DESCRIPTION OF THE DRAWINGS

Preferred embodiments of the present invention will now be described by accompanying drawings in which:

FIG. 1 is a perspective view of the housing in the closed position.

FIG. 2 is a perspective view of the housing in the open position showing installation of the hand held computer.

FIG. 3 is a section view of the electronic dock.

FIG. 4 is a block diagram of the electrical system.

FIG. 5 is a section view the housing showing implementation of a button.

FIG. 6 is a section view of the housing showing implementation of a sensor.

FIG. 7 is a section view of a hand held computer with touchscreen interface representing PRIOR ART.

FIG. 9 is a section view of the present invention novel touchscreen interface.

FIG. 10 is a perspective view showing an embodiment of the present invention using the touchscreen interface.

FIG. 11 is a perspective view of the housing and installed computer display.

### DETAILED DESCRIPTION

The first aspect of the present invention provides a case for protecting a hand held computer under water, the case comprising:
(a) a waterproof housing defining a receptacle for holding the hand held computer;
(b) an electronic dock connected to the housing;
(c) a plurality of buttons extending from an outer surface of the housing and electronically connected to the electronic dock, wherein the buttons transmit control signals to the hand held computer through the electronic dock;
(d) one or a plurality of sensors electronically connected to the electronic dock, wherein data from the sensor or sensors is transmitted to the computer through the electronic dock.

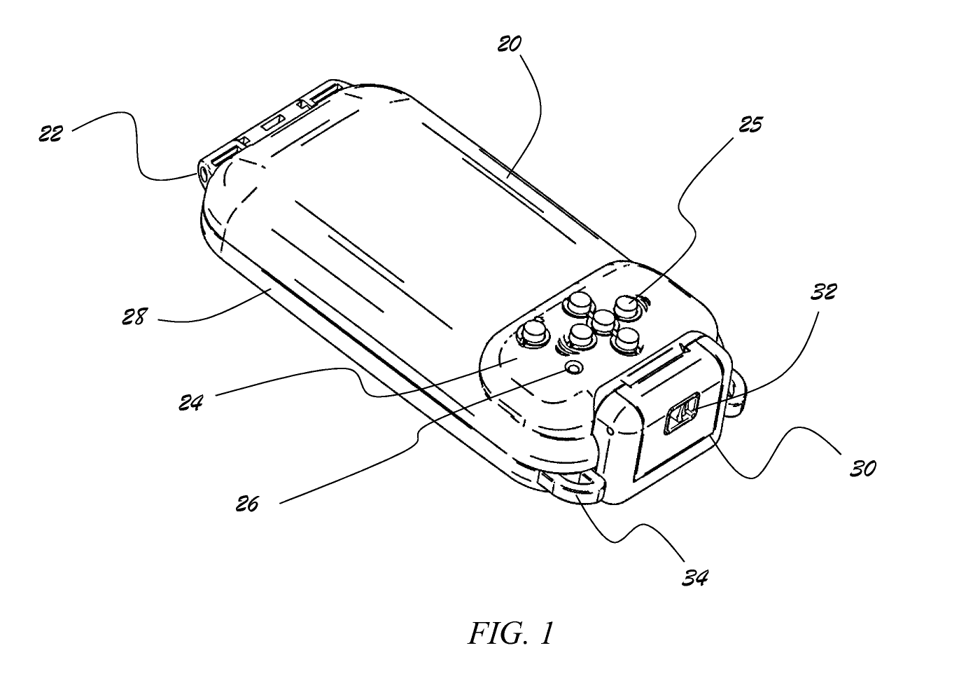

FIG. 1 shows the preferred embodiment of the present invention in a perspective view. The embodiment comprises a front housing 20 made of a transparent plastic material connected to a back housing 28 made of a transparent plastic material by means of a hinge 22. Each housing piece is designed of sufficient structural strength as to maintain shape and not break while subjected to typical diving pressures. An o-ring or other flexible seal is positioned between the front housing 20 and back housing 28 such that the apparatus is watertight when in the closed position shown. A latch 30 is connected to the back housing 28 and hooks over a feature on the front housing 20. When the latch 30 is in the closed position it squeezes and secures the front housing 20 and back housing 28 together over the seal. A latch lock 32 slides within the latch 30 and over a feature of the front housing 20 as to not allow the latch 30 to open unless the lock is manually operated.

The embodiment shown in FIG. 1 comprises a button group 24 protruding from the front housing 20, which provides a method for users to interact with the apparatus. Each button 25 is made of a stainless steel material and is connected to and forms a watertight seal with the front housing 20. The apparatus has a sensor 26 connected to the front housing 20, which measures pressure of the surrounding water or air. In addition this sensor 26 may measure temperature of the surrounding water or air. The sensor 26 is connected to and forms a watertight seal with the front housing 20. A mounting loop 34 is formed into the back housing 28 which provides a method for securing the apparatus to the diver during use. A lanyard or other strap may be tied or otherwise fastened to the apparatus via the mounting loop 34.

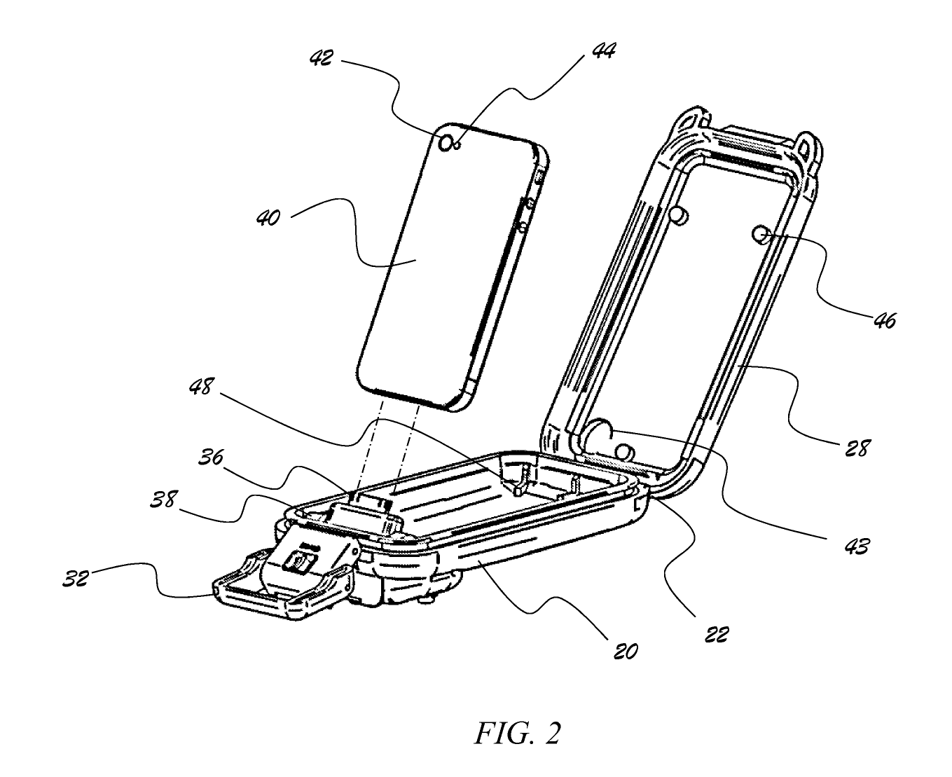

FIG. 2 shows the preferred embodiment of the present invention in a perspective view with the apparatus in the open position for installation of a computer 40. The computer 40 is not part of the present invention in this embodiment, but is used in conjunction with the present invention. The computer 40 is connected mechanically and electrically to the apparatus by means of a connector 36. The connector 36 is connected to an electronic dock 38 which is mounted to the front housing 20.

The computer 40 is installed into the apparatus by insertion of the connector 36 into the corresponding connector on the computer 40. The computer 40 is then lowered into the front housing 20. A plurality of locating features 48 within the front housing 20 position the computer 40 in the desired location for operation. Next the back housing 28 is pivoted on hinge 22 to close the apparatus. The computer 40 is held in place by bumpers 46 which apply downward pressure to the computer 40. The camera aperture 42 and light 44 of the computer 40 are aligned within the apparatus to the camera port 43. This alignment allows these features to be used in operation within the apparatus. The camera port 43 is constructed of a glass window. This glass window is designed as to maintain imaging performance of the camera when used within the apparatus. To complete installation of the computer 40 the latch 32 is closed and locked.

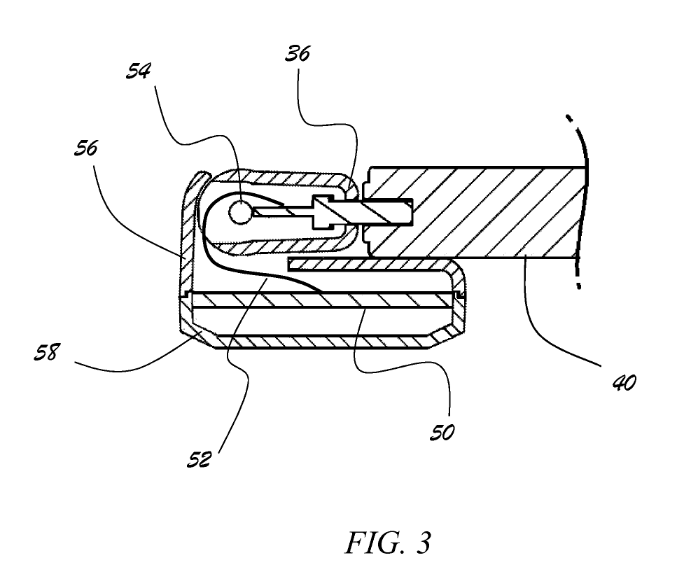

FIG. 3 shows a section view of the apparatus's electronic dock 38. The connector 36 is attached to the upper housing 56 by means of a hinge 54. A flexible electrical interconnect 52 is attached to the connector 36 and the printed circuit board 50 completing an electrical circuit between the apparatus and installed computer 40. The connector 36 pivots on hinge 54 to allow installation of the computer 40 into the apparatus. The upper housing 56 is connected to the lower housing 58 which house and mount the printed circuit board 50 within the front housing 20.

This electronic dock 38 provides an electrical connection between the computer 40 and the apparatuses electronics without the use of an exposed cable. In doing so the apparatus eliminates the possibility of pinching a cable between the housing sections and causing a leak. This is a significant advantage over any prior art.

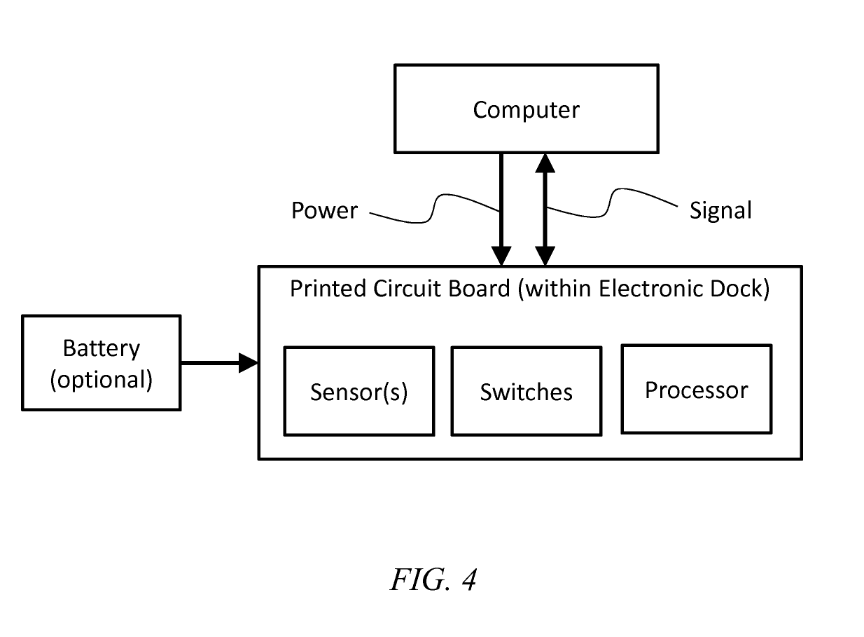

FIG. 4 shows an electrical block diagram of the system with the computer installed in the apparatus. In the preferred embodiment power is supplied by the computer, however optionally power may be supplied by installed batteries. Optionally power from batteries may be supplied to both the printed circuit board and to the computer. In an alternate embodiment the apparatus includes a wireless transmitter to communicate from the printed circuit board to the computer. In yet another alternate embodiment the apparatus includes a wireless receiver to receive pressure measurements from a sensor and transmitter mounted onto the diver's air supply tank. In this embodiment the pressure from the diver's air supply tank can be displayed to the diver on the computer display.

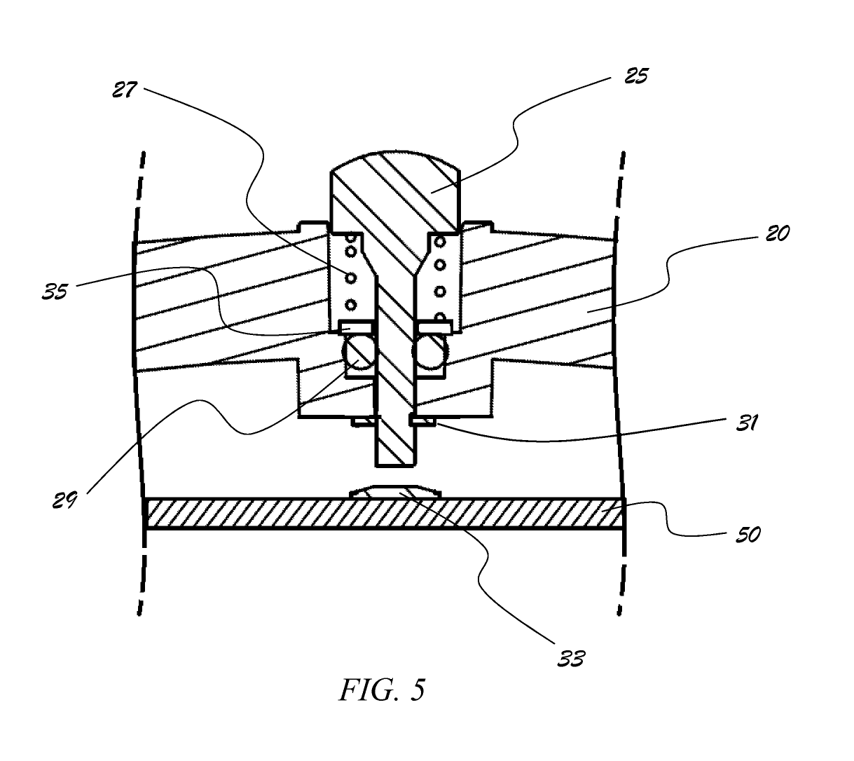

Now referring to FIG. 5, each button 25 is connected to the front housing 20 and forms a seal as shown. A spring 27 provides a force to counteract the force exerted by water pressure during a dive. The spring 27 presses against a seal retaining washer 35. The seal retaining washer 35 retains a seal 29 which creates a watertight seal against the button 25. A retaining clip 31 retains the button 25 within the apparatus. The printed circuit board 50 is connected to the front housing 20. A switch 33 is mounted onto the printed circuit board 50 and positioned directly under the button 25. Depressing button 25 closes the switch 33 contact. A processing component on the printed circuit board 50 detects the switch 33 change, formats the command, and electrically transmits a signal to the computer 40.

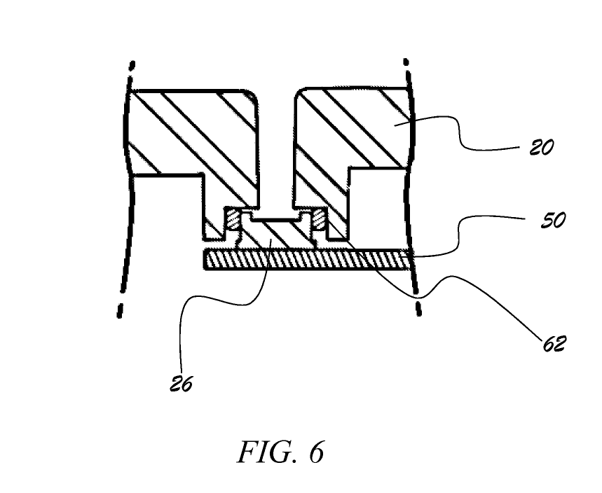

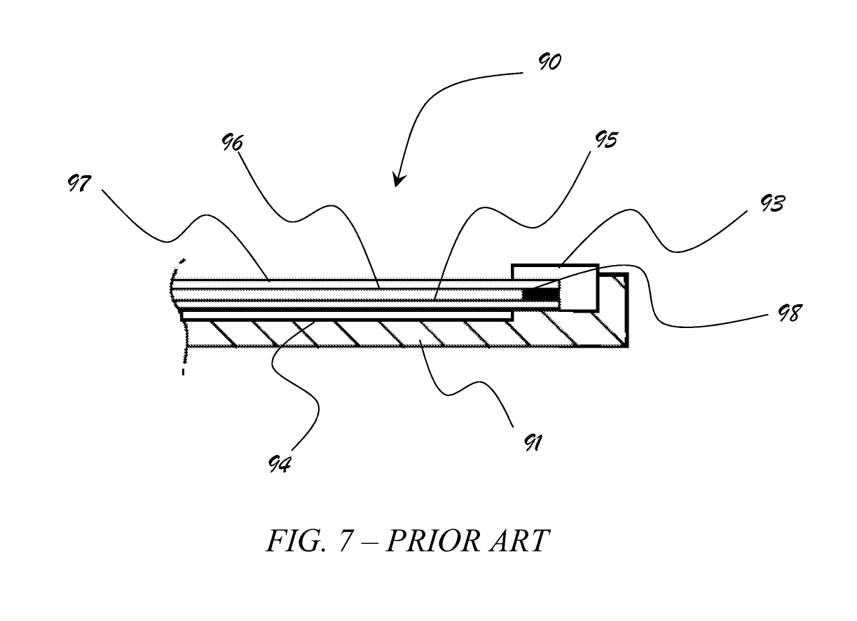

FIG. 6 shows a section view of the sensor 26. The sensor 26 is mounted to the printed circuit board 50. A seal 62 is positioned between the sensor 26 and the front housing 20 which provides a watertight seal. The sensor 26 is exposed to the outside of the apparatus as to measure the pressure and/or temperature of the surrounding air or water. The sensor communicates these measurements electrically to a processing component on the printed circuit board 50 which formats the measurement and electrically transmits the measurement to the computer 40.

FIG. 1-FIG. 6 show the preferred embodiment of the present invention. The apparatus provides the following advantages:
(A) Computer protection: The apparatus protects an installed computer from water damage and damage from elevated pressure.
(B) Diver interface: The apparatus provides a mechanism for converting button presses into electrical signals for transmission to the installed computer.
(C) Robust connection: The apparatus connects to the computer without exposed cables eliminating the risk of pinching cables between the housings creating a water leak during operation. The electronic dock pivots about the hinge to allow easy installation and removal of the computer.
(D) Computer viewing: The transparent housing allows viewing of the installed computer display and viewing to ensure water is not leaking into the case during operation.
(E) Image quality: The apparatus comprises a camera port that aligns with the installed computer's camera and enables pictures and videos to be recorded through the housing. The camera window optic is manufactured to not significantly affect image quality.
(F) Pressure measurement: The apparatus comprises a pressure sensor which measures and digitally transmits data to the installed computer.
(G) Temperature measurement: The apparatus comprises a temperature sensor which measures and digitally transmits data to the installed computer.
(H) Multi-computer fit: In another embodiment the apparatus comprises locating features as to allow more than one model or type of computer to be installed.
(I) Sun shade: In another embodiment the apparatus comprises a sun shade for improved viewing of the computer's display in bright conditions.
(J) External lens mount: In another embodiment the apparatus comprises a feature to retain an externally mounted lens element or color correction optical filter. This feature on the camera port allows lenses to be interchanged which work in conjunction with the installed camera of the computer.

In another embodiment the invention is a combination of apparatuses allowing a handheld computer such as the Apple iPhone to be used under water, the combination comprising:

(a) a waterproof housing defining a receptacle;

(b) an electronic dock connected to the housing;

(c) a hand held computer mounted to the electronic dock and held within the waterproof housing;

(d) a plurality of buttons extending from an outer surface of the housing and electronically connected to the electronic dock, wherein the buttons transmit control signals to the hand held computer through the electronic dock;

(e) one or a plurality of sensors connected to the housing wherein the sensors transmit measurements to the hand held computer through the electronic dock;

(f) a software application installed on the hand held computer.

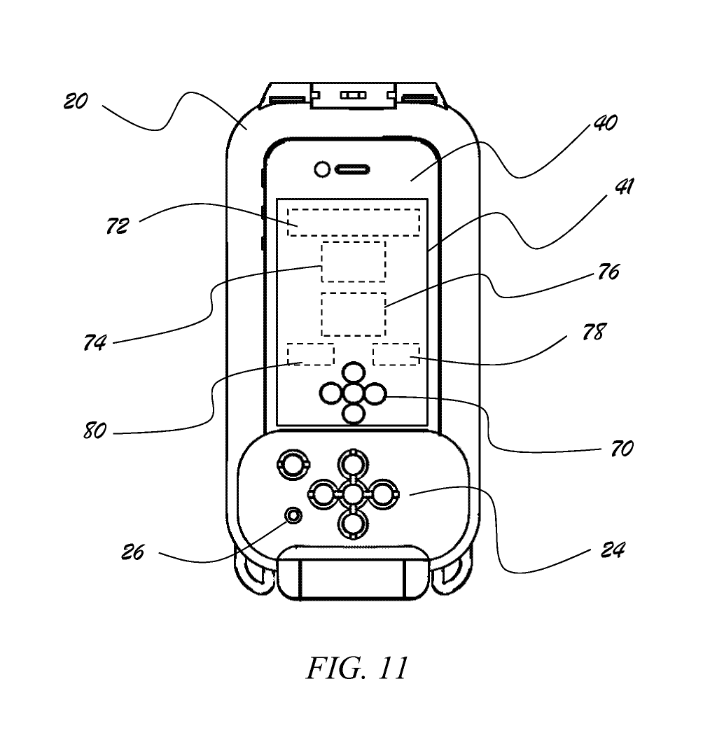

FIG. 11 shows a perspective view of the apparatus with installed computer 40. Front housing 20 being a transparent material allows viewing of a computer display 41. Using sensor 26 and computer 40, the apparatus is able to calculate and display dive parameters to the user. The computer display provides indication of parameter values continuously to the user during a dive or while at the surface. The dive status indicator 72 provides the current mode of operation and the dive time. The depth indicator 74 provides the current depth as measured by sensor 26. The temperature indicator 80 displays current temperature of the air or water in contact with installed sensors. The time indicator 76 displays the time remaining at the current depth to remain in a dive which does not require decompression stops. Max depth indicator 78 displays the maximum depth reached during the current dive.

A graphical representation of button functions 70 provides the user with an indication of the function of each physical button within the button group 24. As the function of the button group 24 may change on each screen displayed to the user, the graphical representation of button functions 70 changes with the screen to display the new functions available to the user.

FIG. 1-FIG. 6 and FIG. 11 are applicable to this combination of apparatuses. This combination of apparatus provides many useful processes and capabilities to the scuba diver in a single multipurpose device. The following processes and capabilities are enabled by this embodiment hereinafter referred to as the system.
(A) User control of system operation: In operation the system accepts user input via button presses. These button press events are converted into electrical signals by the apparatus and communicated to the computer. The computer processes these signals and performs actions based on the software application. Through this process the user may navigate and perform actions within the software application running on the computer while installed within the apparatus.
(B) Dive computer calculations: In operation the system measures the surrounding pressure. This measurement is processed by the apparatus and communicated to the computer. The application installed on the computer receives this measured pressure seen by the invention and approximates the pressure experienced by the diver collocated with the apparatus. The pressure input is converted to an approximation of depth based on the known density of water. The application displays this depth to the diver in real time during the dive. The application uses real time depth data and historical depth data for further calculations typical of dive computers, such as the calculation of the partial pressure of inert gases in the body. The application includes a stopwatch function that begins counting when the application determines the dive has commenced. The application displays the dive time to the user. The application uses elapsed time information for further calculations. The application calculates dive parameters critical for diver safety such as nitrogen loading of the blood stream due to breathing compressed air. The application calculates and displays the remaining safe dive time at the current depth. This calculation is based on the cumulative absorption of nitrogen during the dive and during previous dives. The calculation uses elapsed time and depth profile. In addition the application may include more advanced dive safety calculations based on pressure and time alone or in combination with additional sensors.
(C) Navigation of application: Typical hand held computer software applications such as those common to use on the iPhone are partitioned into individual screens of content to display information to the user. Navigation between screens allows the user to access the desired content to fulfill their intended purpose for using the application. The present system enables navigation within the application by mapping button press events received to the navigation of screens within the application. This allows the user to navigate between screens of content without having access to the native computer interface. During a dive it is important to maintain display of some critical information to the user for example the current depth. The present system provides a novel method of maintaining the persistent display of this information as the user navigates to other screens to access other information or functionality. The application creates a sub-view of critical information such as current depth, time remaining at current depth, air supply pressure, etc. which remains on the screen as the user moves to other content. An additional element of the present system is that in creating the sub-view which carries the main console information to other screens, the system animates the transition of the critical information to the new position on the subsequent screen if it is located in a different screen position. This transition alerts the user to the new location of the information on the subsequent screen. This provides an intuitive and seamless communication of this critical data to the user.
(D) Recording images and video: The system enables capture of images and video in operation. Button press events are used to navigate within the application to access the computer's camera function. After navigation the button press events are mapped to actions to begin recording video, stop recording video, and take a picture. This process enables the capture of media during the dive which is a desirable capability for scuba divers.
(E) Associating captured media to dive: The system constructs a digital dive event or log stored in computer memory. The system's pressure sensor may be used to identify when a dive has begun and when a dive has ended. During the course of a dive, relevant information such as the location of the dive, the time of the dive, water temperature, max depth, depth versus time profile, and media, pictures and video, are recorded in a file structure or stored with additional data that associate the information and media to a specific dive. This process enables the automatic creation of a dive event record for later retrieval or viewing by the user. The application may display a list of dive event records back to the user while installed within the housing or while the user operates the computer outside of the housing. This capability is very important to scuba divers since log keeping is commonplace within the sport.
(F) Enabling compass navigation: The system displays a compass to the user on the computer's display. The computer has a digital compass component. Measurements are accessed by the application and are displayed to the user in real time.
(G) Geographically locating a dive: The system uses a Global Positioning System receiver installed on the computer to gather current coordinates before a dive. When the systems pressure sensor communicates a change in pressure indicating a dive has begun the application records the most current coordinates into memory and associates the coordinates with the dive event.
(H) External camera flash control: The system controls the firing of an external waterproof flash, not a component of the present system but used in conjunction, by the following process. When the user commands the camera to take a picture, the camera calculates whether a flash should be used based on available light measured. If the camera indicates a need for flash, the application signals the external flash by means of pulsing the computer's light. Light pulses emitted by the computer replicate the pre-flash used by many point and shoot cameras. This pre-flash is frequently used to optically queue firing of an external flash in underwater camera systems. By replicating this process with the present invention, the system is compatible with many commercially available external flashes.
(I) Activity feedback indication: The system uses accelerometer and/or gyroscope measurements from the computer to approximate the activity of the diver during a specific dive event. The system provides feedback to the diver in the form of a score for the purpose of making the diver conscious of their activity level with the ultimate goal of reduction air consumption on future dives.
(J) Emergency communication: The system stores for quick access an emergency contact for dialing selected by the user. The system can access and use the phone functionality of the computer to call a preprogrammed number or a number accessed through other methods. Alternatively the system can text an emergency message including the diver's GPS position via the computer's communication network. The emergency dial feature can be preprogrammed with information to send so that sending the emergency message requires little user intervention at the time of need.
(K) Air supply pressure: The system employed with an optional wireless receiver can receive pressure measurements wirelessly from the diver's air supply tank. Devices which mount to the diver's air supply tank and transmit pressure measurements wirelessly are common in the industry. The system can receive these transmissions and display pressure indications to the user on the computer display.

In another embodiment of either the first described apparatus or system, the housing comprises a touchscreen functioning to accept user input while submerged. The touchscreen uses resistive sensing technology, but alternative touchscreen technologies may be used such as, piezo-resistive or piezo-voltaic. The touchscreen is mounted to the housing which provides a rigid structure behind the touchscreen.

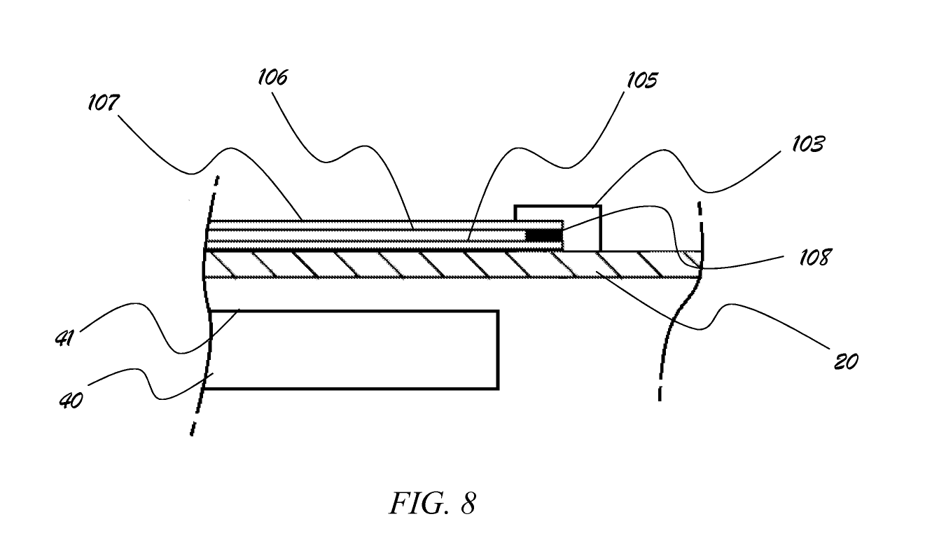

FIG. 7—PRIOR ART shows a section view of a typical hand held computer with a touchscreen interface 90. Conventional resistive touchscreens, consist of a touchscreen inner layer 95 made from glass with a coating of uniform resistivity overlaid by a touchscreen outer layer 97 made from a thin polyester film. The touchscreen outer layer 97 is tightly suspended from the top of the touchscreen inner layer 95 and separated by small, transparent insulating dots and an air filled gap 96. The touchscreen outer layer 97 has a coating of uniform resistivity on the inner side. When the user touches the touchscreen, the resistive coating makes electrical contact with the coating on the touchscreen inner layer 95, and a touch event is registered by the touchscreen controller which measures a change in resistance across the touchscreen in orthogonal directions. A touchscreen spacer 98 seals the perimeter of the touchscreen.

Commonly the touchscreen is mounted to the computer housing 91 by means of a frame 93. The touchscreen is made from transparent materials and is positioned by the frame 93 over the computer display 94. The user can view the computer display 94 through the touchscreen interface. Conventional touchscreens are not suitable for use while submerged underwater. The air filled gap 96 is compressed by the elevated water pressure experienced during a dive until the layers are in contact with or without a user touch event. When this occurs, touch events can no longer be registered and the touchscreen is not operational.

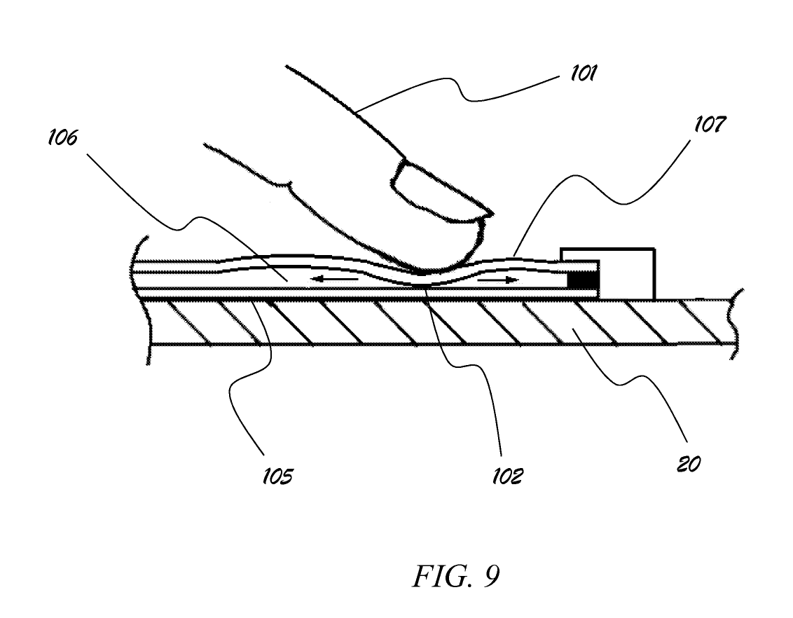

The present embodiment is shown in FIG. 8. This novel touchscreen is designed to be insensitive to the pressure exerted by water during a dive. Several components are common to conventional touchscreens such as touchscreen outer layer 97, touchscreen inner layer 95, frame 93, and touchscreen spacer 98. The primary difference is that a dielectric fluid layer 106 separates the touchscreen outer layer 97 and touchscreen inner layer 95. The dielectric fluid is made from silicone oil, mineral oil, or other insulating fluid suitable for use in contact with the uniform resistive layer. The dielectric fluid layer 106 replaces the air gap 96 (FIG. 7) in the conventional design and resists compression when a uniform pressure is applied. When a localized pressure is applied such as caused by a finger 101 touch event from the user, the dielectric fluid is displaced from between the layers directly under the user's finger 101 as shown in FIG. 9. The flexible touchscreen outer layer 97 allows flow of the dielectric fluid from the area of the touch event. A touch event produces a localized pressure higher than the uniform ambient pressure acting on the invention and forces the two layers into contact. The location of the contact point 102 is measured and communicated to the computer. The touchscreen inner layer shown in FIG. 9 may be omitted in an alternative embodiment. In this alternative embodiment the uniform resistive layer may be printed directly onto the front housing 20.

The invention could use numerous variations of the described fluid filled touchscreen approach with the primary objective being to maintain separation of the cover sheet and glass panel under a uniform pressure. In order to register an intentional touch event the fluid is allowed to flow away from the local touch point into another area within the device. Compliance elsewhere in the separation layer is used to allow displacement with the total volume of the fluid unchanged. This compliance mechanism may be accomplished by many methods by those skilled in the art.

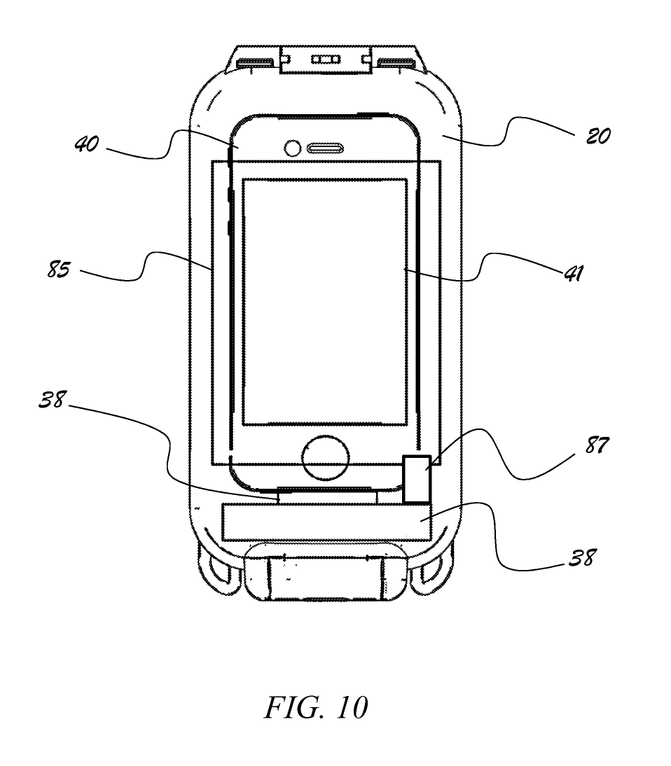

FIG. 10 shows a perspective view of the novel touchscreen applied to the front housing 20 acting as the user interface for the apparatus. The computer 40 is installed and located in the apparatus such that the computer's touchscreen and display 41 is overlaid by the novel touchscreen 85. A flexible interconnect 87 connects the novel touchscreen 85 and the electronic dock 38. The electronic dock 38 connects to the connector 38 which connects to the computer 40. These connections complete a circuit from the novel touchscreen 85 to the computer 40 for transmission of touch events.

FIG. 8-FIG. 10 show the preferred embodiment of the novel touchscreen which provides the significant advantages over prior art. The novel touchscreen allows scuba diving electronics to incorporate touchscreen interfaces which were previously not suited for this application. The novel touchscreen provides a familiar interface to the user by replicating the most common hand held computer interface currently used by industry.

In another embodiment the system previously described additionally comprises this novel touchscreen. In this combination the function of the computer's touchscreen is replicated by the system. The combination of apparatuses which form the system allow the user to interact with the installed computer in a similar manner to the user interaction with the computer when the computer is not used in the housing. This functionality provides a familiar interface to the user common to their normal interaction with the computer.

In this embodiment the system replicates much of the functionality of the original computer touchscreen, however due to differences in touchscreen technology for submerged applications; all functionality may not be supported directly. An example may be a function that requires multi-touch sensing capability, such as the two-finger zoom function on the Apple iPhone. If some functionality of the computer is not supported directly, the application includes provisions to access the same functionality with a method supported by the combined system. The novel touchscreen may be sized larger than the installed computer in order to include additional space for touch events in locations not overlaying the computer display. Within this additional space a single press in a specific location is made to correspond to the same zoom function on the computer. Other functionality can likewise be incorporated with the additional touch space on the novel touchscreen. The application provides a correlation of these commands to the original computer function. Through this manner the original user interface functionality of the computer is maintained while installed within the system.

In an alternate embodiment similar to the novel touchscreen, a flexible membrane keypad is used as the user interface. The air gap between contacts of discrete buttons on the keypad is replaced with a dielectric fluid in the same manner as the novel touchscreen. The fluid is allowed to flow from under the contacts when a button press occurs, however a uniform pressure applied to the flexible membrane has no effect. This modification of conventional keypad designs allows their use for user interfaces in scuba diving equipment.

In another embodiment a touchscreen suitable to underwater use is comprised of a piezo-resistive or piezo-voltaic touchscreen. These touchscreens use force measurements at a plurality of locations on the touchscreen to determine if and where a touch event occurs. To make these common devices suitable for underwater use the controller is made to not respond to uniform pressure fields at all measured points on the touchscreen. The controller will use the measurements of the uniform pressure fields to detect the pressure value exerted on the

What is claimed is:

1. A case for protecting a hand held computer under water, the case comprising:
a. a waterproof housing defining a receptacle for holding the hand held computer;
b. an electronic dock connected to said housing;
c. a plurality of buttons extending from an outer surface of said housing and electronically connected to said electronic dock, wherein said buttons transmit control signals to the hand held computer through said electronic dock.

2. A case for protecting a hand held computer according to claim 1, wherein said housing comprises at least two portions connected by a hinge for opening and closing said housing.

3. A combination of apparatuses allowing a handheld computer to be used under water, the combination comprising:
a. a waterproof housing defining a receptacle;
b. an electronic dock connected to said housing;
c. a hand held computer mounted to said electronic dock and held within said waterproof housing;
d. a plurality of buttons extending from an outer surface of said housing and electronically connected to said electronic dock, wherein said buttons transmit control signals to said hand held computer through said electronic dock.

4. A combination according to claim 3, wherein said hand held computer further comprises a display and non-transitory computer readable media storing a software application that runs on said hand held computer, wherein said software application displays visible data on said display when said display is activated, said visible data including a depth measurement for said hand held computer and a no decompression time limit for a user operating said hand held computer.

5. A combination according to claim 4, wherein said software application displays command icons on said touchscreen in a predetermined pattern, and said buttons on said housing are arranged in said predetermined pattern.

6. A combination according to claim 4, wherein said software application provides more than one screen of content and provides a method of transition between screens using commands from said plurality of buttons.

7. A combination according to claim 4, wherein said software application animates location changes of diving parameters on said computer display during transitions between screens providing knowledge of where the information is displayed on the subsequent screen.

8. A combination according to claim 4, wherein said software application controls activation of external flash through wireless optical communication using a light from said computing device to synchronize firing of said external flash with the capture of an image using a camera from said computing device.

9. A combination according to claim 4, wherein said software application creates a dive event record stored into said computer memory based on input from said electronics module and populates said dive event record with parameters measured by said electronics module and associates captured photographs and video to said dive event record.
